(19) United States
(12) Patent Application Publication
(10) Pub. No.: US 2025/0287852 A1
(43) Pub. Date: Sep. 11, 2025

(54) ROOM TEMPERATURE SUPERCONDUCTING CIRCUIT ELEMENTS AND METHODS OF MANUFACTURING THE SAME

(71) Applicant: Toyota Research Institute, Inc., Los Altos, CA (US)

(72) Inventor: Abraham Silar Anapolsky, San Mateo, CA (US)

(73) Assignees: Toyota Research Institute, Inc., Los Altos, CA (US); Toyota Jidosha Kabushiki Kaisha, Toyota-shi Aichi-ken (JP)

(21) Appl. No.: 18/409,102

(22) Filed: Jan. 10, 2024

Related U.S. Application Data
(60) Provisional application No. 63/523,208, filed on Jun. 26, 2023.

(51) Int. Cl. H10N 60/85; H10N 60/81

(52) U.S. Cl. CPC H10N 60/857; H10N 60/81

(57) ABSTRACT

A superconducting circuit element includes an actuated thin film, with one or more circuit element openings, disposed on a rigid substrate, and an under compression room temperature (UC-RT) superconductor material disposed within the one or more circuit element openings. The actuated thin film includes microcrystalline diamond and applies a compressive strain on the UC-RT superconductor material such that a RT superconducting circuit element is formed on the rigid substrate.

### CROSS-REFERENCE TO RELATED APPLICATIONS

This application claims the benefit of U.S. Provisional Application No. 63/523,208, filed Jun. 26, 2023, which is incorporated herein in its entirety by reference.

### TECHNICAL FIELD

The present disclosure generally relates to electronic circuit elements, and particularly to room temperature superconducting electronic circuit elements.

### BACKGROUND

Superconductor electronics typically combine passive (linear) and active (nonlinear) superconducting elements into circuits and systems that include non-superconducting circuit elements to provide electronic devices such as amplifiers, power sources, and controllers, among others. However, cooling of the superconducting circuit elements below their critical temperature (T_{c}) can be costly.

The present disclosure addresses issues related to superconductor circuit elements, among other issues related to superconductor electronics.

### SUMMARY

This section provides a general summary of the disclosure, and is not a comprehensive disclosure of its full scope or all of its features.

In one form of the present disclosure, a superconducting circuit element includes an actuated thin film, with one or more circuit element openings, disposed on a rigid substrate, and an under compression room temperature (UC-RT) superconductor material disposed within the one or more circuit element openings. The actuated thin film includes microcrystalline diamond and applies a compressive strain on the UC-RT superconductor material such that a RT superconducting circuit element is formed on the rigid substrate.

In another form of the present disclosure, a superconducting circuit element includes an actuated microcrystalline diamond thin film, with one or more circuit element openings, disposed on a rigid substrate, and a UC-RT superconductor material disposed within the one or more circuit element openings such that the actuated microcrystalline diamond thin film applies a compressive strain on the UC-RT superconductor material and a RT superconducting circuit element is formed on the rigid substrate.

In still another form of the present disclosure, a superconducting circuit element includes an ion bombarded microcrystalline diamond thin film, with one or more circuit element openings, disposed on a rigid substrate, and an under compression room temperature (UC-RT) superconductor material disposed within the one or more circuit element openings such that the ion bombarded microcrystalline diamond thin film applies a compressive strain on the UC-RT superconductor material and the RT superconducting circuit element is formed on the rigid substrate.

Further areas of applicability and various methods of enhancing the disclosed technology will become apparent from the description provided herein. The description and specific examples in this summary are intended for purposes of illustration only and are not intended to limit the scope of the present disclosure.

### BRIEF DESCRIPTION OF THE DRAWINGS

The present teachings will become more fully understood from the detailed description and the accompanying drawings, wherein:

FIG. 1A illustrates a side cross-sectional view of a rigid substrate for the manufacture of room temperature (RT) superconducting circuit elements according to the teachings of the present disclosure;

FIG. 1B illustrates the rigid substrate in FIG. 1A with a microcrystalline diamond thin film deposited and/or formed thereon according to the teachings of the present disclosure;

FIG. 1C illustrates FIG. 1B with a mask formed on the microcrystalline diamond thin film according to the teachings of the present disclosure;

FIG. 1D illustrates FIG. 1C with circuit element openings etched into the mask and the microcrystalline diamond thin film according to the teachings of the present disclosure;

FIG. 1E illustrates FIG. 1D with an under compression room temperature (UC-RT) superconductor material deposited within the circuit element openings according to the teachings of the present disclosure;

FIG. 1F illustrates FIG. 1E with UC-RT superconductor material on the rigid substrate and at least partially within the microcrystalline diamond thin film after removal of the mask and excess UC-RT superconductor material according to the teachings of the present disclosure;

FIG. 1G illustrates FIG. 1F with a mask on the UC-RT superconductor material according to the teachings of the present disclosure;

FIG. 1H illustrates FIG. 1G with a strain induced in the microcrystalline diamond thin film via ion bombardment;

FIG. 1I illustrates FIG. 1H after removal of the mask and UC-RT superconducting circuit elements formed on the rigid substrate;

FIG. 2 is a top view of a UC-RT superconductor electronic circuit element with a UC-RT superconductor wire disposed between a pair of strained microcrystalline diamond thin films according to the teachings of the present disclosure;

FIG. 3 is a top view of a Josephson junction according to the teachings of the present disclosure;

FIG. 4 is a circuit diagram of a charge qubit with a Josephson junction according to the teachings of the present disclosure;

FIG. 5 is a superconducting quantum interference device (SQUID) with a pair of Josephson junctions according to the teachings of the present disclosure; and

FIG. 6 is a flow chart for a method of forming UC-RT superconducting circuit elements according to the teachings of the present disclosure.

It should be noted that the figures set forth herein are intended to exemplify the general characteristics of UC-RT superconductor circuit elements of the present technology, for the purpose of the description of certain aspects. These figures may not precisely reflect the characteristics of any given aspect, and are not necessarily intended to define or limit specific embodiments within the scope of this technology. Further, certain aspects may incorporate features from a combination of figures.

### DETAILED DESCRIPTION

The present teachings provide improved or enhanced room temperature (RT) superconducting electronic circuit elements and methods for manufacturing RT superconducting circuit elements. The RT superconducting circuit elements include an under compression-room temperature (UC-RT) superconducting material at least partially embedded in a thin film. As used herein, the phrase “UC-RT superconducting material” refers to a material that exhibits RT superconductivity when subjected to at least a predefined amount of compressive strain. Non-limiting examples of UC-RT superconducting material include yttrium barium copper oxides (YBCO), magnesium diboride (MgB₂), mercury-barium-calcium-copper-oxides (HgBaCaCuO), bismuth strontium calcium copper oxide (BiSrCaCuO), ruthenium(IV) oxide (RuO₂), strontium iridium oxide (Sr₂IrO₄), lanthanum copper oxide (La₂CuO₄), lanthanum copper oxide (LaCuO₃), and europium iron cobalt arsenide (Eu(Fe_{0.88}Co_{0.12})₂As₂), among others.

In some variations, the UC-RT superconducting material is subjected to a compressive strain (pressure) from or by a microcrystalline diamond thin film. For example, in at least one variation a microcrystalline diamond thin film subjected to ion bombardment exhibits a positive strain due to the ion bombardment and thereby applies or imposes a compressive strain on the UC-RT superconducting material. As used herein, the phrase “microcrystalline diamond thin film” refers to a thin film of crystalline diamond with an average grain size ranging between sub-micrometer to single crystal depending on the feature (e.g., electronic element) size.

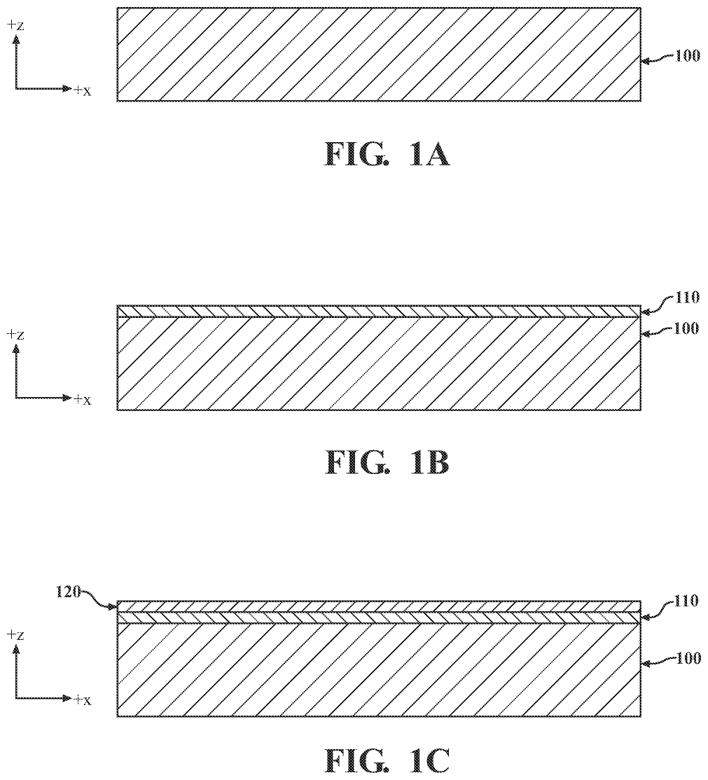

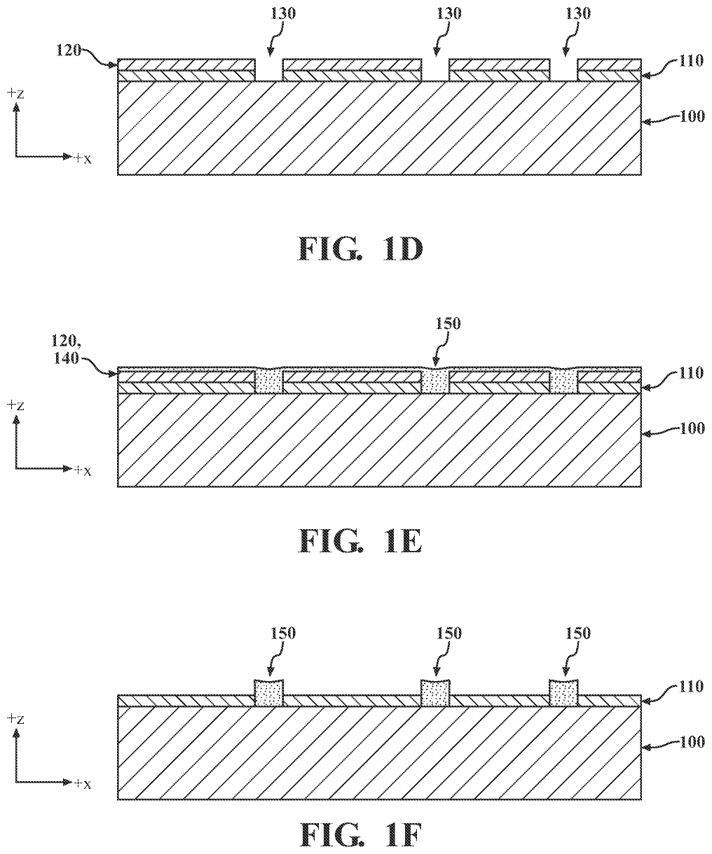

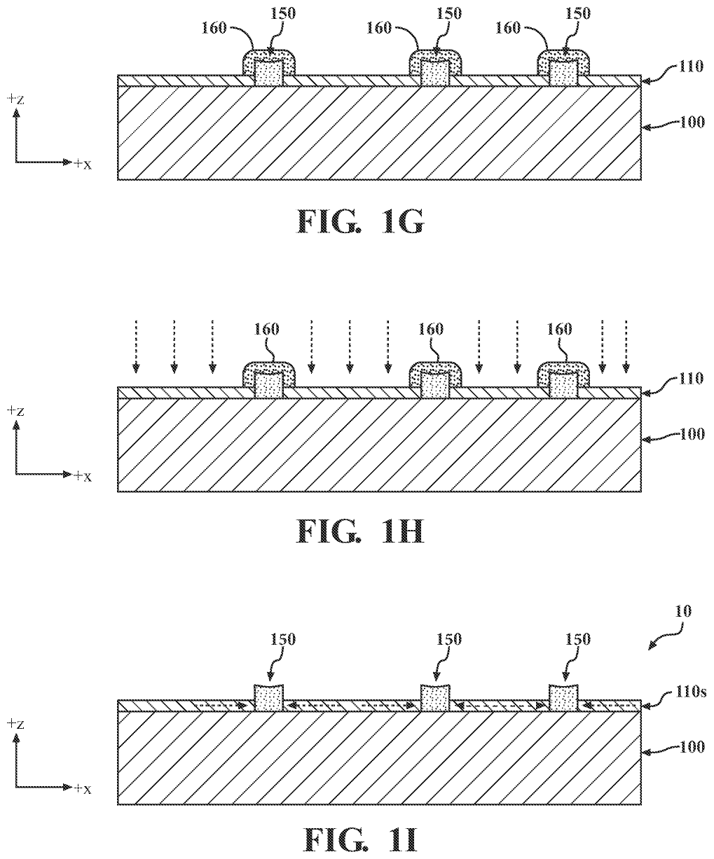

Referring now to FIGS. 1A-1I, illustrative steps for manufacturing RT superconducting circuit elements 10 (FIG. 1I) are shown. Particularly, and with reference to FIGS. 1A-1B, a microcrystalline diamond thin film 110 is deposited onto a rigid substrate 100. Non-limiting examples of the rigid substrate 100 include a silicon substrate (e.g., a silicon wafer), a gallium arsenide substrate, and a germanium substrate, among others. And non-limiting techniques for forming the microcrystalline diamond thin film 110 on the rigid substrate 100 include thin film deposition techniques such as chemical vapor deposition (CVD) techniques (e.g., hot filament chemical vapor deposition with a H₂-rich/CH₄ gas atmosphere) and physical vapor deposition (PVD) techniques.

In some variations, the microcrystalline diamond thin film 100 has an average thickness (z direction) between about 0.5 micrometers (μm) and about 2 millimeters (mm). For example, in some variations, the microcrystalline diamond thin film thin film 100 has an average thickness between about 0.5 μm and about 1 mm, while in other variations the microcrystalline diamond thin film 110 has an average thickness between about 1.0 μm and about 750 μm. Non-limiting examples of an average thickness of the microcrystalline diamond thin film 110 include an average thickness between about 1.0 μm and about 10 μm, between about 10 μm and about 20 μm, between about 20 μm and about 30 μm, between about 30 μm and about 40 μm, between about 40 μm and about 50 μm, between about 50 μm and about 60 μm, between about 60 μm and about 70 μm, between about 70 μm and about 80 μm, between about 80 μm and about 90 μm, between about 90 μm and about 100 μm, between about 100 μm and about 110 μm, between about 110 μm and about 120 μm, between about 120 μm and about 130 μm, between about 130 μm and about 140 μm, between about 140 μm and about 150 μm, between about 150 μm and about 160 μm, between about 160 μm and about 170 μm, between about 170 μm and about 180 μm, between about 180 μm and about 190 μm, between about 190 μm and about 200 μm, between about 200 μm and about 210 μm, between about 210 μm and about 220 μm, between about 220 μm and about 230 μm, between about 230 μm and about 240 μm, between about 240 μm and about 250 μm, between about 250 μm and about 260 μm, between about 260 μm and about 270 μm, between about 270 μm and about 280 μm, between about 280 μm and about 290 μm, between about 290 μm and about 300 μm, between about 300 μm and about 310 μm, between about 310 μm and about 320 μm, between about 320 μm and about 330 μm, between about 330 μm and about 340 μm, between about 340 μm and about 350 μm, between about 350 μm and about 360 μm, between about 360 μm and about 370 μm, between about 370 μm and about 380 μm, between about 380 μm and about 390 μm, between about 390 μm and about 400 μm, between about 400 μm and about 410 μm, between about 410 μm and about 420 μm, between about 420 μm and about 430 μm, between about 430 μm and about 440 μm, between about 440 μm and about 450 μm, between about 450 μm and about 460 μm, between about 460 μm and about 470 μm, between about 470 μm and about 480 μm, between about 480 μm and about 490 μm, and between about 490 μm and about 500 μm.

Referring to FIGS. 1C-1D, the microcrystalline diamond thin film 110 is masked (FIG. 1C) with a masking material 120 (also referred to herein as “mask 120”) and predefined circuit element openings 130 are formed within the mask 120 and microcrystalline diamond thin film 110 (FIG. 1D). As used herein, the terms “masked” and/or “masking” refers to: 1) a hard, or contact, mask made of a thin, a standalone plate made of ceramic, metal, or glass, with through holes for areas that are meant to be treated, etched, etc.; 2) a standard photo-resist mask made in the standard fashion; or 3) a sacrificial thin film layer, such as a metal, dielectric, or semiconductor.

It should be understood that the circuit element openings 130 extend along and at least partially within (−z direction) the microcrystalline diamond thin film 110 in the x- and y-directions illustrated in the figures. In some variations, the circuit element openings 130 are formed within the mask 120 and the microcrystalline diamond thin film 110 using an etching technique, e.g., reactive ion etching. Accordingly, the circuit element openings 130 are designed and/or configured for receiving circuit element material. And in at least one variation, the mask 120 is removed from the microcrystalline diamond thin film 110 and another mask 140 (e.g., a photoresist masking agent) is patterned and applied to the non-patterned area of the microcrystalline diamond thin film 110.

Referring to FIG. 1E, a UC-RT superconducting material 150 is deposited into the circuit element openings 130 and onto the mask 120 or mask 140, and excess UC-RT superconducting material is removed as illustrated in FIG. IF such that only the UC-RT superconducting material 150 deposited into the circuit element openings 130 and the nonpatterned microcrystalline diamond thin film 110 remain. In some variations, the excess UC-RT superconducting material 150 is removed by wet etching, ion etching, etc., and the mask material (e.g., standard photo-resist mask or sacrificial thin film layer mask), is removed via etching in an acid solution, a base solution, or by ion etching. In at least one variation, the remaining UC-RT superconducting material 150 is further processed, for example, thermally processed (annealed) via rapid thermal annealing.

Referring to FIGS. 1G-1I, another mask 160 is applied to the remaining UC-RT superconducting material 150 (FIG. 1G) and the remaining microcrystalline diamond thin film 110 is actuated by being placed in a strained state in the x-direction shown in the figures (FIG. 1H). In some variations, the remaining microcrystalline diamond thin film 110 is placed in the strained state via ion bombardment using heavy noble gases such xenon (Xe), argon (Ar), or other suitable ions, as illustrated by the vertical (z-direction) dotted line arrows in FIG. 1H.

And with reference to FIG. 1I, at least a portion of the strain in the strained microcrystalline diamond thin film 110s is transferred to the UC-RT superconducting material 150 such that the UC-RT superconducting material 150 is under compression as illustrated by the horizontal (x-direction) arrows in the figure and the UC-RT superconducting material 150 is superconductive at RT. Stated differently, the strained microcrystalline diamond thin film 110s places the UC-RT superconducting material under sufficient compressive strain such that the UC-RT superconducting material 150 is superconductive at RT and RT superconducting circuit elements 10 are formed.

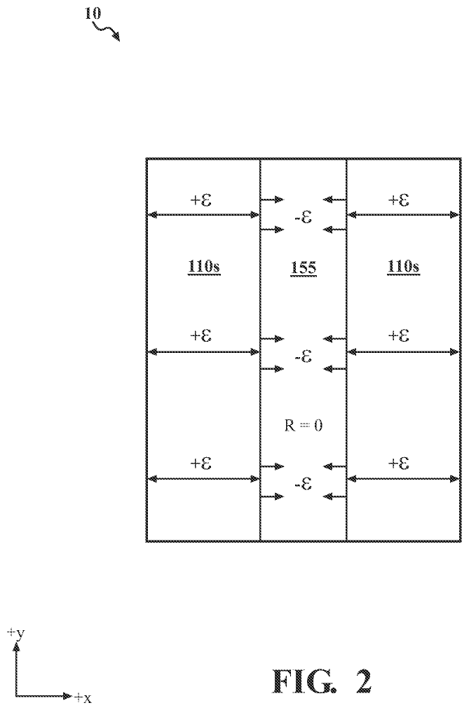

Referring to FIG. 2, a top view of a UC-RT superconducting element 10 according to the teachings of the present disclosure is shown. The UC-RT superconducting element 10 includes a UC-RT superconducting wire 155, formed from the UC-RT superconducting material 150, disposed between a pair of strained microcrystalline diamond thin films 110s. And as illustrated in FIG. 2, the pair of strained microcrystalline diamond thin films 110s exhibit a positive strain +ε which in turn applies a compressive strain (−ε) to the UC-RT superconducting wire 155 such that the UC-RT superconducting wire 155 has a resistance R=0.

For example, and assuming the UC-RT superconducting wire 155 is RuO₂, the strains estimated to induce or cause RT superconductivity in the UC-RT superconducting wire 155 are +1.6% and −0.9%, i.e., about 2%, as disclosed in the reference “Superconductivity in Uniquely Strained RuO₂ Films” by Uchida et al., Phys. Rev. Lett., 125, 147001. In addition, and assuming the UC-RT superconducting wire 155 has a width (x direction) of 0.5 micrometers (μm) and the microcrystalline diamond thin films 110 have a width of 4 μm, the required strain in each microcrystalline diamond thin film 110 is (0.02*0.5 μm)/2=0.005 μm/4 μm=0.00125. Accordingly, subjecting the pair of microcrystalline diamond thin films 110 to ion bombardment transforms the UC-RT superconducting wire 155 into a superconducting electronic element at RT. It should be understood that the amount of ion bombardment the pair of microcrystalline diamond thin films 110 are subjected to depends on the predefined amount of strain imposed or incorporated into the pair of microcrystalline diamond thin films 110, and such strain is parameterized by the ion type, the flux of ions, the time of ion bombardment, and/or the kinetics of the ions.

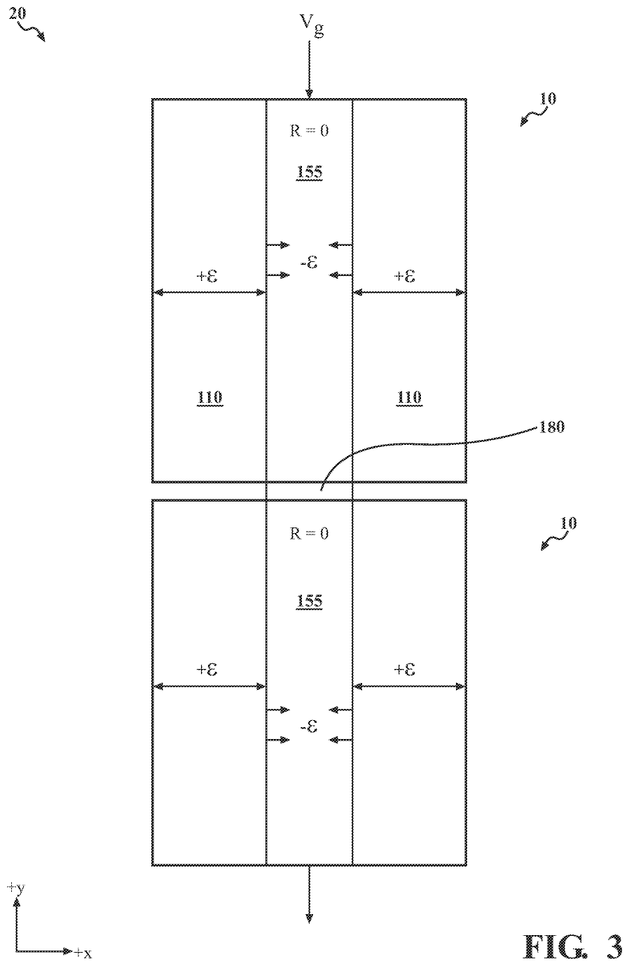

Referring to FIG. 3, a top view of a Josephson junction 20 is shown according to the teachings of the present disclosure is shown. As used herein, the phrase “Josephson junction” refers to a device with two superconducting elements weakly coupled with a region that is either non-superconducting or is weaker superconducting than the two superconducting elements. The Josephson junction 20 includes a pair of the UC-RT superconducting elements 10 discussed above with a thin non-superconducting layer 180 sandwiched therebetween. Particularly, the thin non-superconducting layer 180 is sandwiched between and in direct contact with an upper (+y direction) UC-RT superconducting element 10 and a lower (−y direction) UC-RT superconducting element 10. In some variations, the thin non-superconducting layer 180 has a thickness between about 1 μm and about 10 μm.

During operation, the UC-RT superconducting wires 155 of the upper UC-RT superconducting element 10 and the lower UC-RT superconducting element 10 are superconducting at RT but the thin non-superconducting layer 180 is not superconducting. In addition, applying a voltage V_{g} across the Josephson junction 20 results in Cooper electron pairs (also known simply as “Cooper pairs”) tunnelling (i.e., passing or flowing) through the thin non-superconducting layer 180 via a phenomenon known as the Josephson effect. And it should be understood that controlling the voltage Vg controls the number of Cooper pairs tunneling through the thin non-superconducting layer 180 (i.e., the current) and thereby results in a lossless non-linear inductor. It should also be understood that via the UC-RT superconducting element 10, the Josephson junction 20 is a RT Josephson junction.

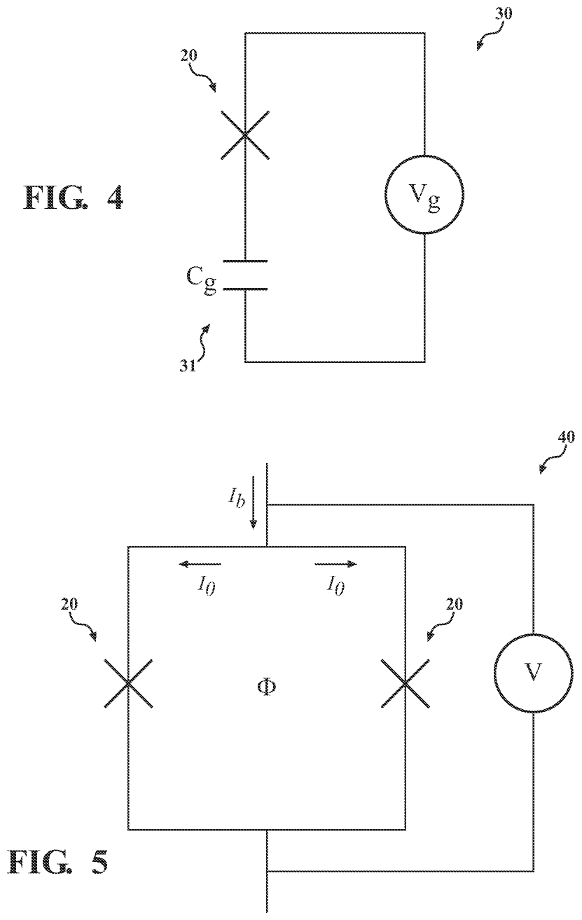

Referring to FIG. 4, a circuit (i.e., a circuit diagram) for a charge qubit 30 is shown. The charge qubit 30 includes a Josephson junction 20 as discussed above (shown or represented by the circuit element symbol “X”) and a capacitor 300. As used herein, the term “qubit” refers to a basic unit of quantum information and the phrase “charge qubit” refers to a qubit whose basis quantum states are charge states (i.e., states which represent the presence or absence of excess Cooper pairs in the thin non-superconducting layer 180). Not being bound by theory, the Josephson junction 20 provides the charge qubit 30 with an anharmonic circuit potential that leads to a non-equidistant spacing of energy levels for the charge qubit 30 and enables unique addressing of each energy level transition. In addition, such superconducting charge qubits, e.g., a RT charge qubit, are used in quantum electronic devices such as quantum computers.

Referring to FIG. 5, a circuit (i.e., a circuit diagram) for a superconducting quantum interference device (SQUID) 40 is shown. As used herein, the term “SQUID” refers to a magnetometer used to measure extremely weak magnetic fields (e.g., as low as 5×10⁻¹⁴ tesla). The SQUID 40 includes a pair of Josephson junctions 20 discussed above. Not being bound by theory, a bias current I_{b} is applied to the SQUID 40 such that a critical current Io flows through the SQUID 40 such that a voltage V is generated and detected in response to a magnetic flux Φ threading (passing through) the SQUID 40. In addition, the SQUID 40, e.g., a RT SQUID 40, can be used as a detector in medical equipment (e.g., magnetoencephalography (MEG), magnetocardiography (MCG), electroencephalogram (EEG) or electrocardiogram (EKG)), military sensors, among others. In addition, in some variations a plurality of SQUIDs 40 are arranged with other circuit elements to form a quantum computing device.

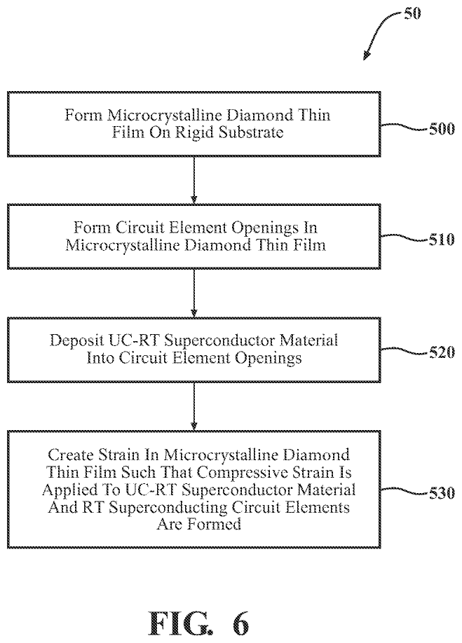

Referring to FIG. 6, a method 50 for forming RT superconducting circuit elements is shown. The method 50 includes forming a microcrystalline diamond thin film on a rigid substrate at 500 and forming circuit element openings in the microcrystalline diamond thin film 110 at 510. The method 50 also includes depositing UC-RT superconductor material into the circuit element openings at 520 and creating a strain in the microcrystalline diamond thin film 110 at 530 such that compressive strain is applied and/or transferred to the UC-RT superconductor material and UC-RT superconducting circuit elements are formed on the rigid substrate.

The preceding description is merely illustrative in nature and is in no way intended to limit the disclosure, its application, or uses. As used herein, the phrase at least one of A, B, and C should be construed to mean a logical (A or B or C), using a non-exclusive logical “or.” It should be understood that the various steps within a method may be executed in different orders without altering the principles of the present disclosure. Disclosure of ranges includes disclosure of all ranges and subdivided ranges within the entire range.

The headings (such as “Background” and “Summary”) and sub-headings used herein are intended only for general organization of topics within the present disclosure, and are not intended to limit the disclosure of the technology or any aspect thereof. The recitation of multiple embodiments having stated features is not intended to exclude other embodiments having additional features, or other embodiments incorporating different combinations of the stated features.

As used herein, the terms “comprise” and “include” and their variants are intended to be non-limiting, such that recitation of items in succession or a list is not to the exclusion of other like items that may also be useful in the devices and methods of this technology. Similarly, the terms “can” and “may” and their variants are intended to be non-limiting, such that recitation that an embodiment can or may comprise certain elements or features does not exclude other embodiments of the present technology that do not contain those elements or features.

The broad teachings of the present disclosure can be implemented in a variety of forms. Therefore, while this disclosure includes particular examples, the true scope of the disclosure should not be so limited since other modifications will become apparent to the skilled practitioner upon a study of the specification and the following claims. Reference herein to one aspect, or various aspects means that a particular feature, structure, or characteristic described in connection with an embodiment or particular system is included in at least one embodiment or aspect. The appearances of the phrase “in one aspect” (or variations thereof) are not necessarily referring to the same aspect or embodiment. It should also be understood that the various method steps discussed herein do not have to be carried out in the same order as depicted, and not each method step is required in each aspect or embodiment.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations should not be regarded as a departure from the disclosure, and all such modifications are intended to be included within the scope of the disclosure. In addition, Attachment A, filed with the present disclosure, is incorporated herein in its entirety by reference.

What is claimed is:

1. A superconducting circuit element comprising:
a room temperature (RT) superconducting circuit element comprising:
an actuated thin film, with one or more circuit element openings, disposed on a rigid substrate, the thin film comprising microcrystalline diamond; and
an under compression room temperature (UC-RT) superconductor material disposed within the one or more circuit element openings such that the actuated thin film applies a compressive strain on the UC-RT superconductor material and the RT superconducting circuit element is formed on the rigid substrate.

2. The superconducting circuit element according to claim 1, wherein the actuated thin film has a thickness between about 0.5 μm and about 2 mm.

3. The superconducting circuit element according to claim 2, wherein the actuated thin film is a microcrystalline diamond thin film.

4. The superconducting circuit element according to claim 2, wherein the actuated thin film is an ion bombarded thin film.

5. The superconducting circuit element according to claim 1, wherein the UC-RT superconductor material is selected from the group consisting of a yttrium barium copper oxide, a magnesium diboride, a mercury-barium-calcium-copper-oxide, a bismuth strontium calcium copper oxide, a ruthenium (IV) oxide, a strontium iridium oxide, a lanthanum copper oxide, a lanthanum copper oxide, and a europium iron cobalt arsenide.

6. The superconducting circuit element according to claim 1, wherein the RT superconducting circuit element is a RT superconducting wire.

7. The superconducting circuit element according to claim 1, wherein the RT superconducting circuit element is a RT Josephson junction.

8. The superconducting circuit element according to claim 1, wherein the RT superconducting circuit element is a RT charge qubit.

9. The superconducting circuit element according to claim 1, wherein the RT superconducting circuit element is a RT superconducting quantum interference device.

10. The superconducting circuit element according to claim 1 further comprising a quantum computing device with the RT superconducting circuit element.

11. The superconducting circuit element according to claim 10, wherein the RT superconducting circuit element is a plurality of RT superconducting circuit elements.

12. A superconducting circuit element comprising:
a room temperature (RT) superconducting circuit element comprising:
an actuated microcrystalline diamond thin film, with one or more circuit element openings, disposed on a rigid substrate; and
an under compression room temperature (UC-RT) superconductor material disposed within the one or more circuit element openings such that the actuated microcrystalline diamond thin film applies a compressive strain on the UC-RT superconductor material and the RT superconducting circuit element is formed on the rigid substrate.

13. The superconducting circuit element according to claim 12, wherein the actuated microcrystalline diamond thin film has a thickness between about 0.5 μm and about 2 mm.

14. The superconducting circuit element according to claim 12, wherein the actuated microcrystalline diamond thin film is an ion bombarded microcrystalline diamond thin film.

15. The superconducting circuit element according to claim 12, wherein the UC-RT superconductor material is selected from the group consisting of a yttrium barium copper oxide, a magnesium diboride, a mercury-barium-calcium-copper-oxide, a bismuth strontium calcium copper oxide, a ruthenium (IV) oxide, a strontium iridium oxide, a lanthanum copper oxide, a lanthanum copper oxide, and a europium iron cobalt arsenide.

16. The superconducting circuit element according to claim 12, wherein the RT superconducting circuit element is selected from the group consisting of a RT superconducting wire, a RT Josephson junction, a RT charge qubit, and a RT superconducting quantum interference device.

17. The superconducting circuit element according to claim 12 further comprising a quantum computing device with the RT superconducting circuit element.

18. A superconducting circuit element comprising:
a room temperature (RT) superconducting circuit element comprising:
an ion bombarded microcrystalline diamond thin film, with one or more circuit element openings, disposed on a rigid substrate; and
an under compression room temperature (UC-RT) superconductor material disposed within the one or more circuit element openings such that the ion bombarded microcrystalline diamond thin film applies a compressive strain on the UC-RT superconductor material and the RT superconducting circuit element is formed on the rigid substrate.

19. The superconducting circuit element according to claim 18, wherein the UC-RT superconductor material is selected from the group consisting of a yttrium barium copper oxide, a magnesium diboride, a mercury-barium-calcium-copper-oxide, a bismuth strontium calcium copper oxide, a ruthenium (IV) oxide, a strontium iridium oxide, a lanthanum copper oxide, a lanthanum copper oxide, and a europium iron cobalt arsenide.

20. The superconducting circuit element according to claim 18, wherein the RT superconducting circuit element is selected from the group consisting of a RT superconducting wire, a RT Josephson junction, a RT charge qubit, and a RT superconducting quantum interference device.
